(19) United States
(12) Patent Application Publication
(10) Pub. No.: US 2007/0130759 A1
(43) Pub. Date: Jun. 14, 2007

(54) Semiconductor device package leadframe formed from multiple metal layers

(75) Inventors: James Harnden, Hollister, CA (US); Anthony Chia, Singapore (SG); Liming Wong, Shanghai (CN); Hongbo Yang, Shanghai (CN)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: GEM Services, Inc., Santa Clara, CA (US)

(21) Appl. No.: 11/416,994

(22) Filed: May 2, 2006

Related U.S. Application Data
(60) Provisional application No. 60/690,958, filed on Jun. 15, 2005.

(51) Int. Cl. H01L 21/00

(52) U.S. Cl. 29/827; 29/825; 438/111; 438/112; 257/666

(57) ABSTRACT

A leadframe having raised features for use a semiconductor device package, is fabricated by bonding together at least two metal layers. A first metal layer may define the lateral dimensions of the leadframe, including any diepad and leads. A second metal layer bonded to the first metal layer, may define the raised features of the leadframe, such as steps for physically securing the leadframe within the package body. The multiple metal layers may be bonded together by a number of possible techniques, including but not limited to ultrasonic welding, soft soldering, or the use of epoxy. Prior to or after bonding, one or more of the metal layers may be coined or stamped to form additional features such as offsets or channels.

### CROSS-REFERENCE TO RELATED APPLICATION

The instant nonprovisional application claims priority to U.S. Provisional Patent Application No. 60/690,958, filed Jun. 15, 2005 and incorporated by reference herein for all purposes.

### BACKGROUND OF THE INVENTION

FIG. 1A shows an underside plan view of a conventional quad flat no-lead (QFN) package utilized to house a semiconductor device. FIG. 1B shows a cross-sectional view taken along line B-B′, of the conventional QFN package of FIG. 1A, positioned on a PC board.

QFN package 100 comprises semiconductor die 102 having electrically active structures fabricated thereon. Die 102 is affixed to underlying diepad 104a portion of lead frame 104 by adhesive 106. The relative thickness of the die and lead frame shown in FIG. 1B, and all other drawings of this patent application, is not to scale. Lead frame 104 also comprises non-integral pin portions 104b in electrical communication with die 102 through bond wires 108. Bond wires 108 also allow electrical communication between die 102 and diepad 104a.

Plastic molding 109 encapsulates all but the exposed portions 104a′ and 104b′ of the lead frame portions 104a and 104b, respectively. For the purposes of this patent application, the term “encapsulation” refers to partial or total enveloping of an element in a surrounding material, typically the metal of the lead frame within a surrounding dielectric material such as plastic.

Portions of the upper surface of lead frame 104 bear silver Ag 105 formed by electroplating. The lower surface of lead frame 104 bears a layer of Pd/Ni or Au/Ni 107 formed by electroplating.

QFN package 100 is secured to traces 110 of underlying PC board 112 by solder 114 that preferably has the rounded shape indicated. The electrically conducting properties of solder 114 allows electrical signals to pass between lead frame portions 104a and 104b and the underlying traces 110.

FIG. 1C shows a plan view of only the lead-frame 104 of QFN package 100 of FIGS. 1A-B. Lead frame 104 is typically formed by etching a pattern of holes completely through a uniform sheet of copper. FIG. 1D shows one example of such a pattern of holes 116 in a copper roll 118. These patterns of holes define a proto-lend frame 122 comprising proto-diepad 124 and proto-non-integral portions 126. Proto-diepad 124 is secured to the surrounding metal frame by tie bars 120. Proto-non-integral pin portions 126 are secured to the surrounding metal frame by tabs 128.

The patterned metal portion shown in FIG. 1D is processed into a package by gluing a die to the diepad, and connecting bond wires between the die and non-integral portions and/or the diepad. While the diepad and non-integral portions are still attached to the surrounding metal, the bond wires and a portion of the diepad and non-integral lead frame portions are encapsulated within a dielectric material such as plastic. Fabrication of an individual package is then completed by severing the tabs and tie bars to singulate an individual package from its surrounding metal frame and other packages associated therewith.

While adequate for many purposes, the conventional QFN package just described offers some possible drawbacks. One possible drawback is the difficulty of forming raised features on the lead frame.

For example, FIG. 1B shows that non-integral lead frame pin portions 104b exhibit a thinned region 104b′ proximate to the diepad. Thinned pin region 104b′ is surrounded on three sides by the plastic encapsulant 109 of the package body, thereby physically securing non-integral pin portion 104b within the package.

Moreover, FIG. 1B also shows that diepad portions 104a exhibit a thinned region 104a′ proximate to the non-integral pins. Thinned diepad region 104a′ is surrounded on three sides by the plastic encapsulant of the package body, thereby physically securing the diepad with the package.

FIGS. 1E-1H show cross-sectional views of the conventional process steps for fabricating a lead frame having a thinned portion. In FIG. 1E, the inverted Cu sheet 118 is electroplated on its bottom surface with an Au/Pd/Ni combination or an Ag/Ni combination to form layer 107. For the Au/Pd/Ni combination, the Au is between about 0.01-0.015 μm in thickness, the Pd is between about 0.02-0.2 μm in thickness, and the Ni is between about 0.5-2.5 μm in thickness. For an Ag/Ni electroplated coating, Ag and Ni are each between about 0.5-2.5 μm in thickness.

In FIG. 1F, photoresist mask 150 is patterned over layer 107 to expose the regions 152 that are to be thinned. Exposed regions 152 are then exposed to an etchant for a controlled period, which removes Cu material to a predetermined depth Y.

In FIG. 1G, the photoresist mask is removed, and Cu roll 118 is then reoriented right side up. The upper surface of the Cu roll 118 is then selectively electroplated to form silver layer 105. The silver may be electroplated only in specific regions over the substrate utilizing a mask (not shown) during this step.

In FIG. 1H, the backside of partially-etched Cu sheet 118 is patterned with a photoresist mask 119 leaving exposed areas 121 corresponding to the thinned regions. The partially-etched Cu sheet 118 is then etched completely through in the exposed areas 121 to form a pattern of holes 116 separating diepad 104a from non-integral pins 104b.

Fabrication of the QFN package is subsequently completed by affixing the die to the diepad, attaching bond wires between the die and diepad and non-integral pin portions, and then enclosing the structure within plastic encapsulation, as is well known in the art.

The etching stage of the QFN package fabrication process shown in FIG. 1F is relatively difficult to control with precision. Specifically, the accuracy of etching the Cu lead frame in small areas is about 20-25% of the total lead frame thickness. This is due to inability to rapidly and reproducibly halt the progress of chemical etching reaction once it is initiated. Etching outside the above tolerance range can result in the scrapping of many lead frames, elevating package cost.

Moreover, the conventional approach of partial etching to shape thinned features limits the pitch of the lead, and thus the number of pins available for a given QFN package body size. This limitation in lead pitch results from the at least partially isotropic character of the etching process, which removes material in the lateral, as well as vertical, direction.

Traditionally, etched leadframes have been used for prototyping new products and for rapidly producing initial limited volumes. Once the leadframes were accepted and quantities of shipped products began to increase, most leadframe designs were tooled such that the leadframes were punched from sheets of copper or other metal. The initial costs of tooling to produce the punched leadframe was usually significantly greater than the first run of etched leadframes. With greater volumes, however, the cost per leadframe of the punched leadframes amounted to only a fraction of the cost of etching a leadframe. However, the simple punch process does not allow the “stepped edge” features described above, to be created.

Another fabrication process that has been used extensively with stamped leadframes in the past is “coining”. The term is taken from the process of stamping features into metals, as in the stamping of coins. This is most commonly used, in regard to semiconductor leadframes, to form features like “moats” that help arrest the spread of soft solder during reflow, and surface patterns that improve adhesion of the die attach epoxy or encapsulant. FIGS. 2A and 2B show a simplified perspective and cross-sectional views of a leadframe having such a feature.

The coining process however, does not remove metals, it simply reforms the metal. Therefore, if the area that is to be thinned extends over a significant percentage of a leadframe feature, coining is not generally a useful process for leadframes.

Therefore, there is a need in the art for improved, and more cost effective techniques for fabricating the leadframes for QFN and similar leadless semiconductor device packages.

### BRIEF SUMMARY OF THE INVENTION

An embodiment of a leadframe in accordance with the present invention having raised features for a semiconductor device package, may be fabricated by bonding together at least two metal layers. A first metal layer defines the lateral dimensions of the leadframe, including any diepad and leads. A second metal layer bonded to the first metal layer, defines the raised features of the leadframe, such as steps for physically securing the leadframe within the package body. The multiple metal layers may be bonded together by a number of possible techniques, including but not limited to ultrasonic welding, by soft soldering, or the use of epoxy. Prior to or after bonding, one or more of the metal layers may be coined or stamped to form additional features such as offsets or channels.

An embodiment of a method in accordance with the present invention for fabricating a lead frame for a semiconductor device package, the method comprising providing a first metal layer defining a leadframe, providing a second metal layer defining raised features of a leadframe; and bonding the first metal layer to the second metal layer.

An embodiment of a leadframe in accordance with the present invention, for a semiconductor device package, comprises, a first metal layer defining a leadframe, and a second metal layer bonded to the first metal layer and defining raised features.

An embodiment of a semiconductor device package in accordance with the present invention comprises a die supported on a leadframe, the leadframe comprising a first metal layer bonded to a second metal layer, the second metal layer defining raised features of the leadframe.

These and other embodiments of the present invention, as well as its features and some potential advantages are described in more detail in conjunction with the text below and attached figures.

### BRIEF DESCRIPTION OF THE DRAWINGS

FIG. 1A shows a simplified underside plan view of a conventional QFN package.

FIG. 1B shows a simplified cross-sectional view of the package of FIG. 1A taken along line B-B′.

FIG. 1C shows a simplified plan view of the lead frame only, of the conventional package of FIGS. 1A-B.

FIG. 1D shows a simplified plan view of a copper alloy metal sheet bearing a pattern of holes as is used to fabricate the package of FIGS. 1A-B.

FIGS. 1E-1H show simplified cross-sectional views of specific steps for fabricating the lead frame of FIG. 1C.

FIGS. 2A-B show simplified perspective and cross-sectional views, respectively, of a leadframe package including a typical solder moat and moisture barrier.

FIG. 3A shows a simplified exploded view of two parts of a multi-layer leadframe before lamination.

FIGS. 3B-C show simplified cross-sectional and plan views, respectively, of the leadframe of FIG. 3A after lamination of the two metal layers.

FIGS. 3D-E show simplified cross-sectional and plan views, respectively, of an alternative embodiment of a leadframe comprising multiple metal layers.

FIG. 3F shows a simplified underside view of a package having the leadframe of FIGS. 3D-E.

FIG. 3G shows a simplified underside view of a package having an alternative embodiment of a leadframe in accordance with the present invention.

FIG. 4A shows a simplified schematic view of one embodiment of a method in accordance with the present invention for forming a leadframe from multiple metal layers.

FIG. 4B shows a simplified exploded view of an embodiment of a multiple metal layer leadframe in accordance with an embodiment of the present invention, featuring channels formed by coining.

FIG. 4C shows a simplified exploded inverted view of a leadframe for a leadless power package with the bonding areas down-set (raised in drawing) to a level approximately equal to the thickness of the die.

FIG. 4D shows the bottom view of the encapsulated package using the leadframe of FIG. 4C.

FIGS. 5A-D show various simplified views of a bondwired die with the electrical contacts to the die (bondwires) re-distributed to take advantage of the die's tighter layout rules.

FIG. 6A shows a simplified plan view of an embodiment of a package including a multi-layer leadframe in accordance with the present invention, having electrical and mechanical attachments made with standard solder balls on each of the die bonding pads.

FIG. 6AA shows a simplified cross-sectional view of the package of FIG. 6A, taken along line A-A′.

FIG. 6AB shows a simplified cross-sectional view of the package of FIG. 6A, taken along line B-B′.

FIG. 6B shows a simplified plan view of an alternative embodiment of a package including a multi-layer leadframe in accordance with an embodiment of the present invention, having electrical and mechanical attachments made with standard solder bumps on each of the die bonding pads.

FIG. 6BA shows a simplified cross-sectional view of the package of FIG. 6B, taken along line A-A′.

FIG. 6BB shows a simplified cross-sectional view of the package of FIG. 6B, taken along line B-B′.

FIG. 7A shows a simplified plan view of an embodiment of a single-die package including a multi-layer leadframe in accordance with the present invention.

FIG. 7AA shows a simplified cross-sectional view of the package of FIG. 7A, taken along line A-A′.

FIG. 7AB shows a simplified cross-sectional view of the package of FIG. 7A, taken along line B-B′.

FIG. 7B shows a simplified plan view of an embodiment of a two-die package including a multi-layer leadframe in accordance with an embodiment of the present invention.

FIG. 7BA shows a simplified cross-sectional view of the package of FIG. 7B, taken along line A-A′.

FIG. 7BB shows a simplified cross-sectional view of the package of FIG. 7B, taken along line B-B′.

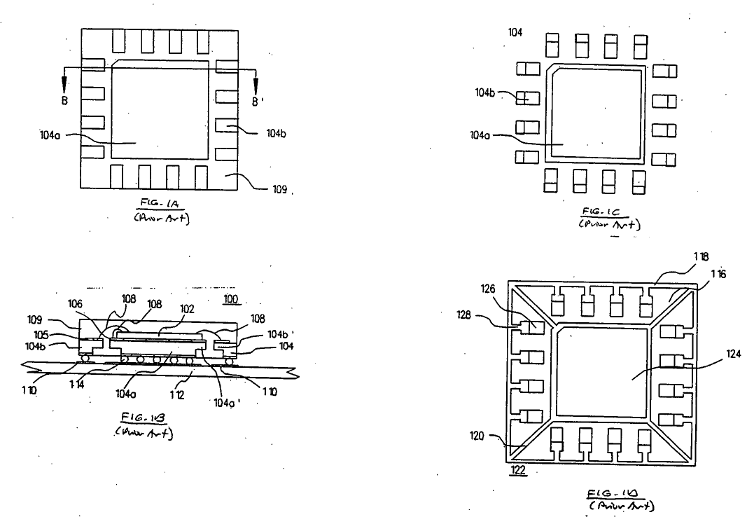

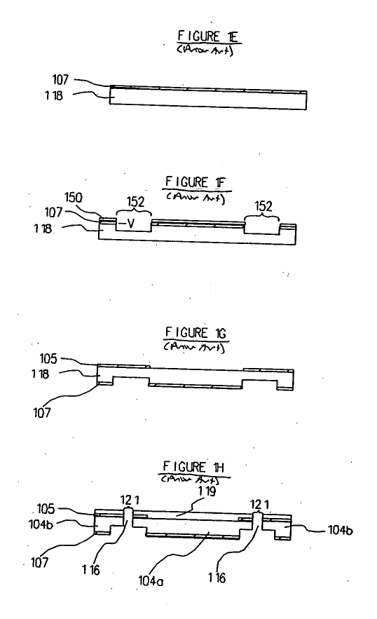

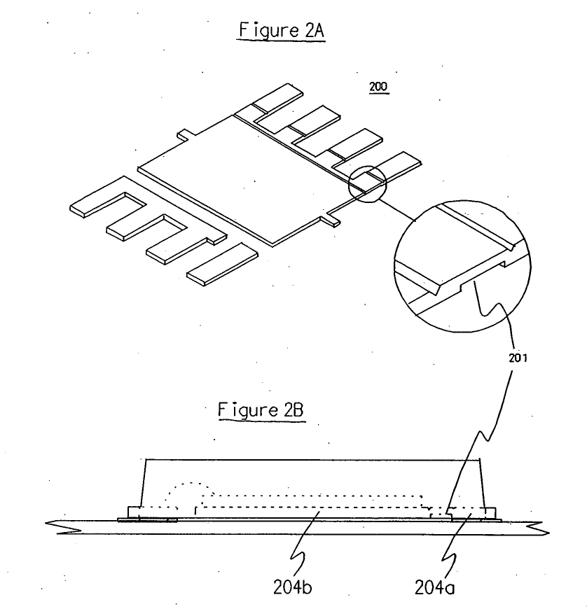

### DETAILED DESCRIPTION OF THE INVENTION

A leadframe in accordance with an embodiment of the present invention having raised features for a semiconductor device package, may be fabricated by bonding together at least two metal layers. A first metal layer defines the lateral dimensions of the leadframe, including any diepad and leads. A second metal layer bonded to the first metal layer, defines the raised features of the leadframe, such as steps for physically securing the leadframe within the package body. The multiple metal layers may be bonded together by a number of possible techniques, including but not limited to ultrasonic welding, by soft soldering, or the use of epoxy. Prior to or after bonding, one or more of the metal layers may be coined or stamped to form additional features such as offsets or channels.

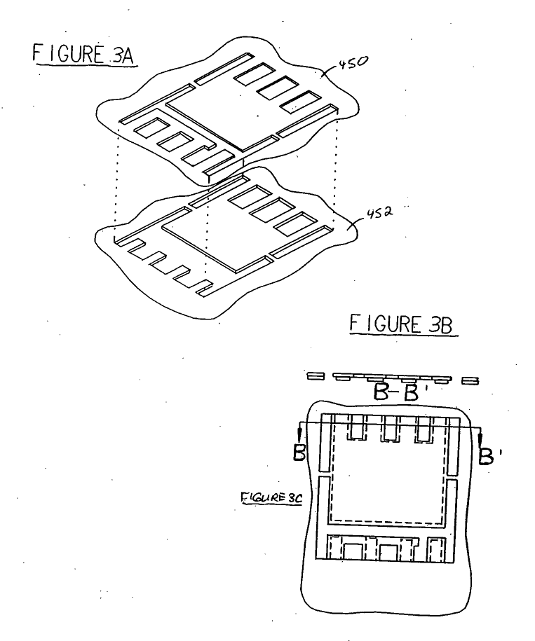

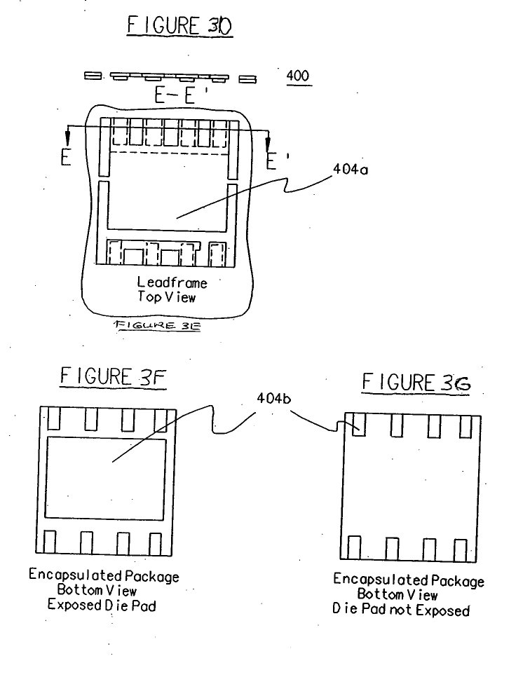

In one embodiment in accordance with the present invention, the locking and moisture resistance can be achieved with similar shaped features as those demonstrated previously, by stamping two leadframes with the area of the top leadframe 450 forming the areas on the top or die side (FIG. 3A) of the leadframe and the bottom half 452 forming the copper that will be exposed for electrical and thermal connections on the bottom of the package (FIG. 3B). The resulting footprint is illustrated in FIG. 3F. The two layers 450 and 452 of the leadframe can also be laminated to form a single copper leadframe with the locking features described previously for the pins, and large areas like the die pad 404a (FIG. 3E) can be a single layer, which allow it to be encapsulated with plastic and not exposed on the bottom of the package (FIG. 3E).

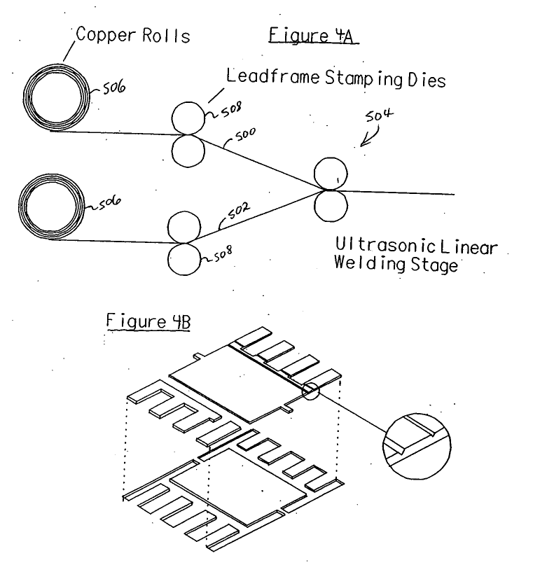

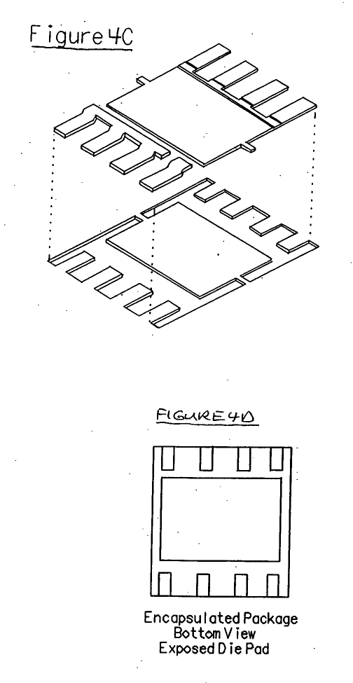

Lamination of the two leadframe layers can be accomplished using one of several methods. One lamination method uses two leadframe layers 500 and 502 of copper that are fused together using a linear feed ultrasonic welding process 504. In high-volume production this process can be arranged to take leadframe material from two rolls of copper 506 directly through two parallel linear stamping stages 508, aligned and fed through a linear ultrasonic welding stage before the leadframes are cut into lengths that feed through existing handling equipment. (FIG. 4A)

Embodiments in accordance with the present invention are not limited to two layers of identical material, or two layers of equal thickness—or even to two layers. It may be advantageous to use two different copper based alloys to optimize bonding to the die or to the PC Board or to increase ruggedness of the exposed surface. It may also prove advantageous to laminate two layers of different metals. Several metal combinations lend themselves to the ultrasonic welding method of lamination and many others can be combined if one surface is pre-plated with an interface or barrier material.

Features that may be coined into the surface of the leadframe, such as solder moats or moisture penetration barriers, can be included in the same process as with a single layer copper leadframe (FIG. 4B). The laminated leadframe can also be stamped to form features such as up-sets or down-sets on the laminated sections of the leadframe, (FIG. 4C). A multi-layer leadframe process could be designed that allows individual layers to be coined or offset prior to lamination. In these cases, it may prove advantageous to cut the leadframes to length and laminate the layers using a stage designed to apply heat and pressure to individual or groups of standard matrix length sections.

An alternative lamination process that may prove economical is to soft solder the two layers of the leadframe together. Careful control of placement and the amount of solder between the two leadframe halves could minimize the amount of “squeeze out” along the outside of the seams. Any solder squeeze-out along the junction would be difficult to remove and would thin the plastic encapsulant in the final package which could lead to failures of the plastic material. Although simple leadframe designs could be made to be more tolerant to solder squeeze-out, and several methods of controlling the solder placement and amount could prove economical and reliable in a manufacturing environment, in accordance with one embodiment the soft-solder process would be to pre-plate one half of the leadframe material with a thin layer of solder. Lamination can then be accomplished in a linear stage that heats the leadframe material to the solder reflow temperature, and brings the leadframe layers together under a controlled pressure.

Another alternative embodiment would use epoxy to laminate the leadframe layers. Current epoxy deposition controls are adequate to laminate simple leadframes. As “screen printing” of semiconductor wafers with both conductive and non-conductive epoxy becomes more routine, it may well become the process of choice for lamination.

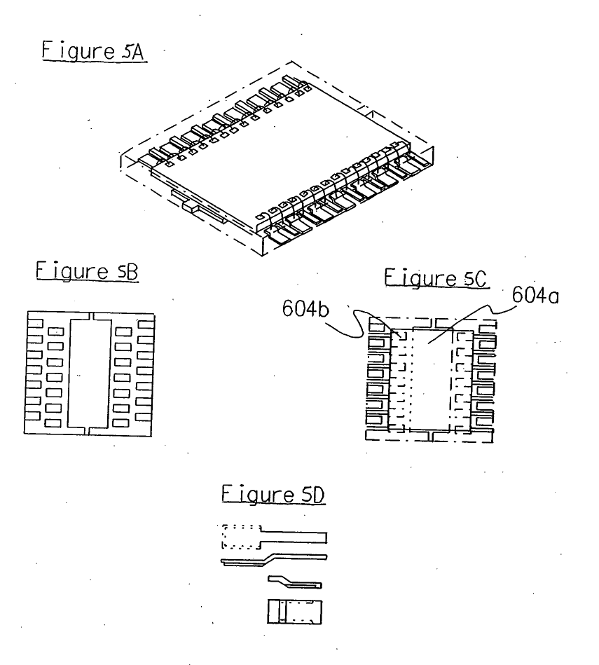

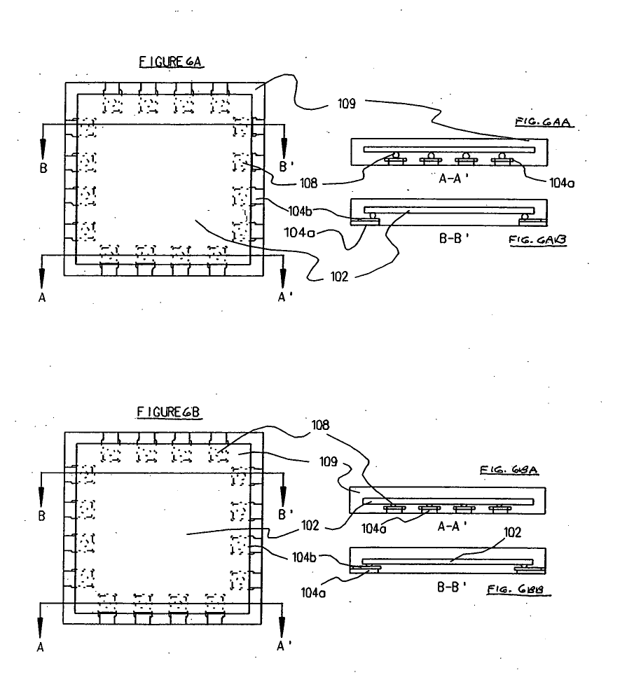

One advantage epoxy offers is a choice of conductive and non-conductive bonding materials, that could be printed in patterns that allow two overlapping leadframe layers, or a die-leadframe interface can be in electrical and/or thermal contact (see diepad 604a of the embodiment shown in FIG. 5C) while two others on the same leadframe/die might be attached mechanically and still be electrically isolated (see lead 604b of the embodiment shown in FIG. 5C). This may become a lower profile, more controllable, and more reliable method for isolating two adjacent layers than leaving space between layers for injection molding to fill and provide isolation.

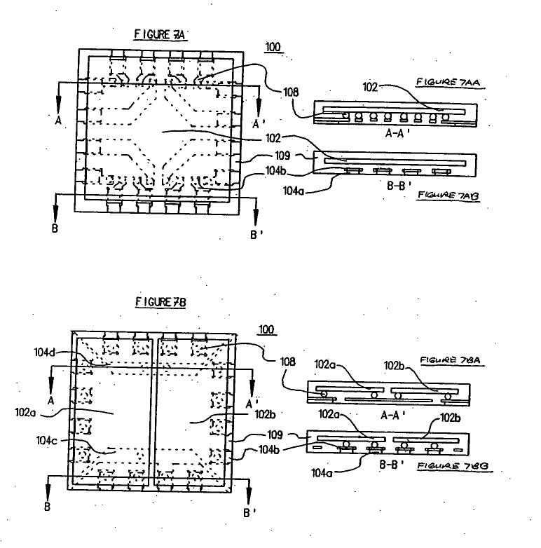

When multilayer leadframes are combined with flip-chip methods of die attachment/electrical connection, the die pad can be eliminated completely. FIGS. 6A-AB illustrate die attachment using a “ball” process. FIG. 6A shows an assembled multi-layer leadframe (layers 104a and 104b) assembly with a die (102) attached “flip-chip”, with electrical and mechanical attachments made with standard solder balls (108) on each of the die bonding pads. An advantage of the flip-chip attached configuration shown in FIG. 6A, when compared to the previous bondwired versions of the same package, is the greatly increased die size. A disadvantage of this configuration is that it forces the die to conform to the layout and spacing rules of the PC board. The contacts to the PC Board are still on 0.5 mm pitch, beyond which, PC Board manufacturing becomes much more expensive, and the die spacing rules would allow a much tighter pitch, which wastes space on the die.

FIGS. 6B-BB illustrate die attachment using a “bump” process. FIG. 6B shows an assembled multi-layer leadframe (layers 104a and 104b) assembly with a die (102) attached “flip-chip”, with electrical and mechanical attachments made with standard solder “bumps” (108) on each of the die bonding pads.

Other embodiments in accordance with the present invention may allow use of the leadframe under a flip-chip attached die, to reassign pinouts or interconnect two or more die. For example, feature sizes on the die are much smaller than those of the PC Board, so traditionally, the bonding pads for wires or for bump or ball electrical connections have had to be spaced and sized to match those of traditional packages, which had to meet pin spacing compatible with PC Board technology. One approach to overcoming this issue is to redistribute the interconnect pads (balls or bumps) on the die, in order to save silicon area. This advantage can be demonstrated when electrical connections to the die are bondwired, but the advantage is even more pronounced when die are bumped and flip-chip attached to the leadframe.

With the bump pad placement and size optimized so the electrical contacts consume minimal space on a die, the bottom of the leadframe can be designed in accordance with embodiments of the present invention to spread the connections to the leads, which are placed in a row or rows consistent with PC Board design rules. FIGS. 7A-AB illustrate a standard 0.5 mm pitch, QFN package (100) with the bonding pads and balls or bumps (108) on 0.25 mm pitch to save space on the (single) die (102). All of the “routing” is done on the upper layer (104b) layer of the leadframe and the only leadframe exposed on the back side of the package after encapsulation is the lower layer (104a) of the leadframe.

This approach may also be utilized to allow space-efficient connection to multiple dies housed within a single package. FIGS. 7B-BA illustrate a standard 0.5 mm pitch, QFN package (100) with the bonding pads and balls or bumps (108) distributed in a pattern that will physically support dual die (102). Demonstrated in this example are two alternatives for interconnection between the die. Interconnect 104d is the same layer as 104b, and electrically connects the electrical nodes on the two die without making connection to a pin that leads to the outside of the package. The other interconnect 104c, (again layer 104b which is not exposed on the package backside) electrically connects nodes on the two die and also connects to an external pin.

Moreover, in multi-die assemblies, interconnection of nodes on different dies that have no need to be brought to the outside on a pin, is a common occurrence. Thus in accordance with further embodiments in accordance with the present invention, traces can be run under the die to interconnect nodes on separate die in multi-die assemblies. By making the interconnect traces single layer, they can be completely encapsulated.

Embodiments of the present invention similar to those shown in FIGS. 7A-B could address a need for applications like Modulated DC-DC power conversion, where the frequency is continually increased to make components smaller and efficiencies higher. The need to keep the PWM controller—power stage—to output device connections as close as possible, and as free of stray inductance as possible, may be important. At some frequency, the die can be co-located within a common package, and bondwires alone will necessitate bump or ball attach. Coined features and/or stamped “up-set” or “down-set” features can be used in conjunction with multilayer leadframes in accordance with embodiments of the present invention, to accomplish isolated interconnections between die with stray inductance reduced by about an order of magnitude from traditional solutions using die in separate, bondwired packages.

In addition to the use of multilayer copper leadframes in accordance with embodiments of the present invention described above, isolation of layers or portions of layers in a package could require “pre-encapsulation” of layers or portions of layers, of the leadframe before the die is attached and electrically or thermally connected to the leadframe. Pre-encapsulation of layers or portions of layers can also add additional capabilities like holding isolated landing pads for interconnections and providing isolated supports for securely clamping the leadframe during high energy bonding processes and/or cutting or “tearing” processes, as required during Aluminum ribbon bonding.

Raised patterns on a leadframe created by the use of multiple metal layers in accordance with embodiments of the present invention may be useful for QFN packages as well as other package types, including but not limited to DPAK, D2PAK, TO-220, TO-247, SOT-223, TSSOP-x, SO-x, SSOP-x, TQFP, and the J-lead family of packages including SE70-8, TSOP-8, and TSOP12.

While the above is a full description of the specific embodiments, various modifications, alternative constructions and equivalents may be used. Therefore, the above description and illustrations should not be taken as limiting the scope of the present invention which is defined by the appended claims.

What is claimed is:

1. A method of fabricating a lead frame for a semiconductor device package, the method comprising:
providing a first metal layer defining a leadframe;
providing a second metal layer defining raised features of a leadframe; and
bonding the first metal layer to the second metal layer.

2. The method of claim 1 wherein the first metal layer is bonded to the second metal layer by ultrasonic welding.

3. The method of claim 1 wherein the first metal layer is bonded to the second metal layer by an epoxy.

4. The method of claim 1 wherein the first metal layer is bonded to the second metal layer by solder.

5. The method of claim 1 wherein the second metal layer is patterned to form the raised feature on a diepad of a power-type package selected from the group consisting of DPAK, D2PAK, TO-220, TO-247, SOT-223, TSSOP-x, SO-x, SSOP-x, TQFP, SE70-8, TSOP-8, and TSOP12.

6. The method of claim 1 wherein the second metal layer is patterned to form the raised feature as a step securing a lead within a plastic body.

7. The method of claim 1 wherein the second metal layer is patterned to form the raised feature as trace connecting two die in a package.

8. The method of claim 1 wherein the second metal layer is patterned to form the raised feature as trace connecting distributing a die contact to a periphery of the package.

9. A leadframe for a semiconductor device package, the leadframe comprising:
a first metal layer defining a leadframe; and
a second metal layer bonded to the first metal layer and defining raised features of the leadframe.

10. The leadframe of claim 9 wherein the second metal layer is welded to the first metal layer.

11. The leadframe of claim 9 further comprising epoxy between the first and second metal layers.

12. The leadframe of claim 9 further comprising solder between the first and second metal layers.

13. The leadframe of claim 9 wherein the raised feature comprises a step securing a lead within a plastic package body.

14. The leadframe of claim 9 wherein the raised feature comprises a conducting trace connecting two die in a package.

15. The leadframe of claim 9 wherein the raised feature comprises a conducting trace distributing a die contact to a package periphery.

16. A semiconductor device package comprising a die supported on a leadframe, the leadframe comprising a first metal layer bonded to a second metal layer, the second metal layer defining raised features of the leadframe.

17. The package of claim 16 wherein the second metal layer is bonded to the first metal layer by welding, epoxy, or solder.

18. The package of claim 16 wherein the raised feature is selected from a step securing a lead within a body of the package, a conducting trace connecting the die with a second die within the package body, or a conducting trace distributing a die contact to a periphery of the package body.
